(19) United States
(12) Patent Application Publication
(10) Pub. No.: US 2012/0132246 A1
(43) Pub. Date: May 31, 2012

(54) PHOTOVOLTAIC MODULES WITH IMPROVED ELECTRICAL CHARACTERISTICS AND METHODS THEREOF

(75) Inventors: Thomas Hunt, Oakland, CA (US); Anders Swahn, Tiburon, CA (US); Wolfgang Harald Oels, Richmond, CA (US)

(73) Assignee: Alion, Inc., Richmond, CA (US)

(21) Appl. No.: 13/116,996

(22) Filed: May 26, 2011

Related U.S. Application Data
(60) Provisional application No. 61/348,974, filed on May 27, 2010.

(51) Int. Cl. H01L 31/05; H01L 31/18

(52) U.S. Cl. 136/244; 438/73; 257/E31.113

(57) ABSTRACT

Photovoltaic module and method for making same. The module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar.

### 1. CROSS-REFERENCES TO RELATED APPLICATIONS

This application claims priority to U.S. Provisional Application No. 61/348,974, filed May 27, 2010, commonly assigned and incorporated by reference herein for all purposes.

### 2. BACKGROUND OF THE INVENTION

The present invention is directed to photovoltaic modules. More particularly, the invention provides photovoltaic modules with improved electrical characteristics and methods thereof. Merely by way of example, the invention has been applied to photovoltaic modules including various types of photovoltaic materials such as silicon, cadmium telluride, CIGS, and/or organics. But it would be recognized that the invention has a much broader range of applicability.

Photovoltaics convert light (e.g., sunlight) into electricity, providing a desirable source of clean energy. A conventional photovoltaic module includes a semiconductor layer divided up into a series of interconnected cells wherein each cell may have a width ranging from 5 mm to 1 cm. Depending upon its characteristics and other factors, each cell often generates a voltage of between 500 mV DC and 1V DC. Usually, a photovoltaic module (e.g. a solar panel) includes 100 or more cells across its face and has a typical width of about 1 meter. By interconnecting the cells in the module together in series, it is possible to generate a voltage ranging from 100 volts DC to 400 volts DC across the module.

A typical photovoltaic array often contains multiple photovoltaic modules. The photovoltaic modules usually are connected together, at least in series, to form strings of modules using cables or other electrical interconnection mechanisms. The number of modules that can be series connected in each string often is limited by practical considerations that establish a maximum system voltage. The maximum system voltage of a photovoltaic array may be 600, 1000, or 1500 volts DC.

In addition to wiring between modules in a string, each string of modules often includes at least a wired connection to system voltage at one end, and usually another wired connection to system ground at the other end. Reducing the wiring between modules and the wiring to system voltage and system ground in a photovoltaic array can save material, labor, and construction costs.

To reduce the total wiring in a photovoltaic array, it is often desirable to increase the length of a module string without exceeding the maximum system voltage. One way to achieve a longer string is to reduce the number of cells interconnected in series per unit length by increasing the length of individual photovoltaic cells. This presents certain challenges to the photovoltaic module designer. For example, the length of a cell in a photovoltaic module is limited by the resistive losses of the cell. A cell often includes a transparent conductor on the front side of the cell (i.e., the side of the cell designed to receive incident light, which is converted into electricity). The resistive losses in the transparent conductor usually depend, in part, on the length of the cell. For longer cells, (e.g., for cells greater than 1 cm in length) the resistive losses may become quite severe.

Hence, it is highly desirable to improve techniques for reducing the number of cells that are interconnected in series per unit length.

### 3. BRIEF SUMMARY OF THE INVENTION

The present invention is directed to photovoltaic modules. More particularly, the invention provides photovoltaic modules with improved electrical characteristics and methods thereof. Merely by way of example, the invention has been applied to photovoltaic modules including various types of photovoltaic materials such as silicon, cadmium telluride, CIGS, and/or organics. But it would be recognized that the invention has a much broader range of applicability.

According to one embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first back electrode is located between the first front electrode and the second front electrode. The second front electrode is located between the first back electrode and the second back electrode. The first sub-module and the second sub-module are different and the first bus bar and the second bus bar are different.

According to another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell including a second back electrode. Additionally, the method for making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first back electrode between the first front electrode and the second front electrode and placing the second front electrode between the first back electrode and the second back electrode. The process for forming a first sub-module on the substrate and the process for forming a second sub-module on the substrate are different. The process for forming a first bus bar and the process for forming a second bus bar are different.

According to yet another embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first back electrode is located between the first front electrode and the second front electrode. The second back electrode is located between the first front electrode and the second front electrode. The first sub-module and the second sub-module are different and the first bus bar and the second bus bar are different.

According to yet another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell includes a second back electrode. Additionally, the method for making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first back electrode between the first front electrode and the second front electrode and placing the second back electrode between the first front electrode and the second front electrode. The process for forming a first sub-module on the substrate and the process for forming a second sub-module on the substrate are different. The process for forming a first bus bar and the process for forming a second bus bar are different.

According to yet another embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell including a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first front electrode is located between the first back electrode and the second back electrode. The second front electrode is located between the first back electrode and the second back electrode. The first sub-module and the second sub-module are different and the first bus bar and the second bus bar are different.

According to yet another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell includes a second back electrode. Additionally, the method of making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first front electrode between the first back electrode and the second back electrode and placing the second front electrode between the first back electrode and the second back electrode. The process for forming a first sub-module on the substrate and the process for forming a second sub-module on the substrate are different. The process for forming a first bus bar and the process for forming a second bus bar are different.

According to yet another embodiment, a photovoltaic sub-module includes a first photovoltaic cell and a second photovoltaic cell. The first photovoltaic cell includes a first p-type semiconductor layer, a first n-type semiconductor layer, and a first back electrode. The second photovoltaic cell includes a second p-type semiconductor layer, a second n-type semiconductor layer, and a second back electrode. Additionally, the photovoltaic module includes a front electrode, a first bus bar, and a second bus bar. The front electrode is electrically connected to the first photovoltaic cell and the second photovoltaic cell. The first bus bar is electrically connected to the front electrode. The second bus bar is electrically connected to the first back electrode and the second back electrode. The first p-type semiconductor layer and the second p-type semiconductor layer are not directly connected. The first n-type semiconductor layer and the second n-type semiconductor layer are not directly connected. The first bus bar and the second bus bar are different.

According to yet another embodiment, a method for making a photovoltaic sub-module includes providing a substrate, forming a first photovoltaic cell on the substrate, and forming a second photovoltaic cell on the substrate. The first photovoltaic cell includes a first p-type semiconductor layer, a first n-type semiconductor layer, and a first back electrode. The second photovoltaic cell includes a second p-type semiconductor layer, a second n-type semiconductor layer, and a second back electrode. Additionally, the method for making a photovoltaic sub-module includes forming a front electrode, electrically connecting a first bus bar to the front electrode, and electrically connecting a second bus bar to the first back electrode and the second back electrode. The front electrode is electrically connected to the first photovoltaic cell and the second photovoltaic cell. The first p-type semiconductor layer and the second p-type semiconductor layer are not directly connected. The first n-type semiconductor layer and the second n-type semiconductor layer are not directly connected. The process for forming a first bus bar and the process for forming a second bus bar are different.

Many benefits are achieved by way of the present invention over conventional techniques. Certain embodiments optimize the electrical characteristics of a photovoltaic module. For example, depending upon the embodiment, different voltage and current characteristics can be obtained for photovoltaic modules of the same size. In another example, a higher current and a lower voltage can be achieved for a photovoltaic module. Some embodiments reduce the cost of field installation of a photovoltaic module by reducing the number of cells that are interconnected in series per unit length. According to some embodiments, the sharing of contacts between neighboring cells improves the packing fraction of the active area on a photovoltaic panel, thus improving power output.

Depending upon the embodiment, one or more of these benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIG. 1 is a simplified diagram showing a planar view of a photovoltaic module according to one embodiment of the present invention.

FIG. 2 is a simplified diagram showing a side view of the photovoltaic module 100 according to one embodiment of the present invention.

FIG. 3 is a simplified diagram showing a method for making the photovoltaic module according to one embodiment of the present invention.

FIG. 4 is a simplified diagram showing a planar view of a photovoltaic module according to another embodiment of the present invention.

FIG. 5 is a simplified diagram showing a side view of the photovoltaic module according to another embodiment of the present invention.

FIG. 6 is a simplified diagram showing a method for making the photovoltaic module according to one embodiment of the present invention.

FIG. 7 is a simplified diagram showing a planar view of a photovoltaic sub-module according to one embodiment of the present invention.

FIG. 8 is a simplified diagram showing a cross-sectional view of the photovoltaic sub-module according to one embodiment of the present invention.

FIG. 9 is a simplified diagram showing a method for making the photovoltaic sub-module according to one embodiment of the present invention.

### 5. DETAILED DESCRIPTION OF THE INVENTION

The present invention is directed to photovoltaic modules. More particularly, the invention provides photovoltaic modules with improved electrical characteristics and methods thereof. Merely by way of example, the invention has been applied to photovoltaic modules including various types of photovoltaic materials such as silicon, cadmium telluride, CIGS, and/or organics. But it would be recognized that the invention has a much broader range of applicability.

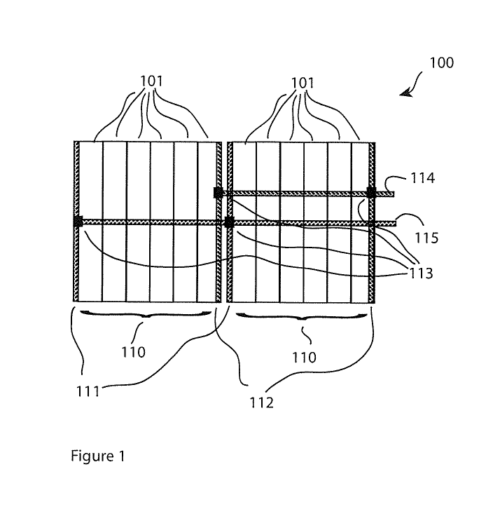

FIG. 1 is a simplified diagram showing a planar view of a photovoltaic module according to one embodiment of the present invention. This diagram is merely an example, which should not unduly limit the scope of the claims. One of ordinary skill in the art would recognize many variations, alternatives, and modifications. In FIG. 1, the photovoltaic module 100 includes a plurality of photovoltaic cells 101. In one example, the photovoltaic cells 101 are interconnected to neighboring photovoltaic cells 101. In another example, the photovoltaic cells 101 are thin film photovoltaic cells.

According to one embodiment, the photovoltaic cells 101 are interconnected to form a plurality of sub-modules 110. In one example, each of the plurality of sub-modules 110 are different in their locations even if they include the same internal structure. In another example, each of the sub-modules 110 includes a sub-module front contact 111. In yet another example, each of the sub-module front contacts 111 are different in their locations even if they include the same internal structure. In yet another example, each of the sub-modules 110 includes a sub-module back contact 112. In yet another example, each of the sub-module back contacts 112 are different in their locations even if they include the same internal structure. In yet another example, one or more of the sub-module front contacts 111 include elements for resistance reduction such as metal foil to reduce electrical resistive losses. In yet another example, one or more of the sub-module back contacts 112 include elements for resistance reduction such as metal foil to reduce electrical resistive losses.

According to another embodiment, the sub-module front contacts 111 are connected (e.g., wired) together, and the sub-module back contacts 112 are connected (e.g., wired) together. For example, the sub-module front contacts 111 are connected to one or more front bus bars 115 using one or more interconnects 113. In another example, each of the one or more front bus bars 115 are different in their locations even if they include the same internal structure. In yet another example, the sub-module back contacts 112 are connected to one or more back bus bars 114 using one or more additional interconnects 113. In yet another example, each of the one or more back bus bars 114 are different in their locations even if they include the same internal structure. In yet another example, the plurality of sub-modules 110 are connected in parallel by the one or more bus bars 114 and 115 through the interconnects 113. In yet another example, one or more of the front bus bars 115 and/or the back bus bars 114 include one or more metal foils. In yet another example, one or more of the front bus bars 115 and/or the back bus bars 114 includes one or more wires. In yet another example, one or more of the front bus bars 115 and/or the back bus bars 114 are insulated to prevent shorting to the backs of the photovoltaic cells 101 and/or to each other.

According to yet another embodiment, the interconnects 113 provide one or more low resistance connections between the sub-module front contacts 111 and the front bus bars 115, and/or provide one or more low resistance connections between the sub-module back contacts 112 and the back bus bars 114. In one example, the interconnects 113 provide a physical contact between conductive materials (e.g. metals). In another example, the interconnects 113 use one or more conductive adhesives. In yet another example, the interconnects 113 use one or more ultrasonic welds. In yet another example, the interconnects 113 use one or more solder joints (e.g., low temperature solder joints).

According to yet another embodiment, the number of photovoltaic cells 101 per sub-module 110 can be varied depending upon the desired current and voltage characteristic needed for the photovoltaic module 100. In one example, each sub-module 110 includes a one or more photovoltaic cells 101. In another example, each sub-module 110 includes as many as half the photovoltaic cells 101 included in the photovoltaic module 100.

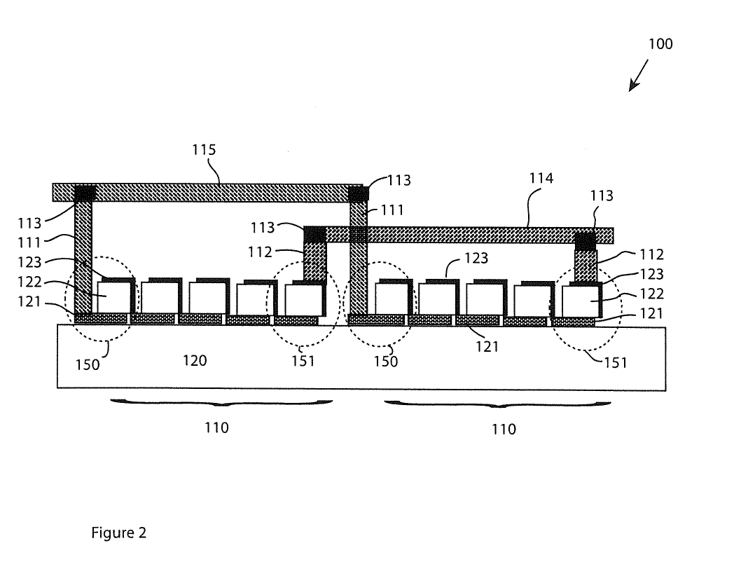

FIG. 2 is a simplified diagram showing a side view of the photovoltaic module 100 according to one embodiment of the present invention. This diagram is merely an example, which should not unduly limit the scope of the claims. One of ordinary skill in the art would recognize many variations, alternatives, and modifications. In FIG. 2, the photovoltaic module 100 includes a plurality of interconnected sub-modules 110. For example, all of the sub-modules 110 are mounted on a substrate 120. In another example, all of the sub-modules 110 are mounted on the same substrate 120. In yet another example, each of the sub-modules 110 are oriented the same way so that an end portion 150 of each of the sub-modules 110 are connected to sub-module front contacts 111 and another end portion 151 of each of the sub-modules 110 are connected to sub-module back contacts 112.

According to one embodiment, each of the photovoltaic cells 101 includes an active layer 122 coupled between a front electrode 121 and a back electrode 123. In one example, the active layer 122 includes an n-type semiconductor region, including a material such as cadmium sulfide, and a p-type semiconductor region, including a material such as cadmium telluride. In another example, the n-type semiconductor region is coupled between the p-type semiconductor region and the front electrode 121. In yet another example, the P-type semiconductor region is coupled between the n-type semiconductor region and the back electrode 123. In yet another example, one or more of the front electrodes 121 are of a transparent conductive material such as a metal oxide. In yet another example, as shown in FIG. 2, the front electrode 121 of a photovoltaic cell 101 is coupled to the back electrode 123 of another photovoltaic cell 101 within the same sub-module 110. In yet another example, the front electrode 121 in the end portion 150 of each of the sub-modules 110 is coupled to a corresponding sub-module front contact 111. In yet another example, the back electrode 123 in the end portion 151 of each of the sub-modules 110 is coupled to a corresponding sub-module back contact 112.

As discussed above and further emphasized here, FIGS. 1 and 2 are merely examples, which should not unduly limit the scope of the claims. One of ordinary skill in the art would recognize many variations, alternatives, and modifications. For example, each of the plurality of sub-modules 110 is replaced by at least two modules that are interconnected in series. In another example, one or more of the front bus bars 115 and/or the back bus bars 114 are replaced by conductive materials in other forms. In yet another example, each of the plurality of photovoltaic cells 101 includes one or more photovoltaic materials (e.g., silicon, cadmium telluride, CIGS, and/or organics). In yet another example, the n-type semiconductor region is coupled between the p-type semiconductor region and the back electrode 123. In yet another example, the p-type semiconductor region is coupled between the n-type semiconductor region and the front electrode 121.

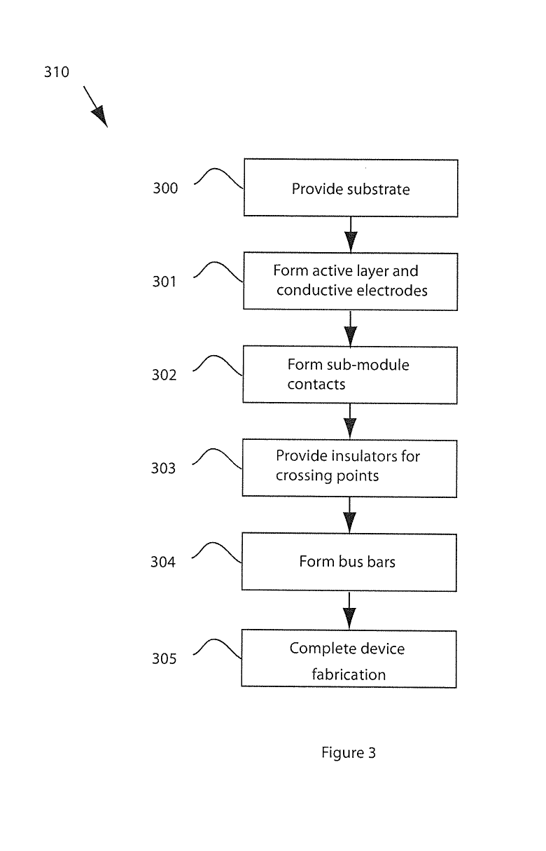

FIG. 3 is a simplified diagram showing a method for making the photovoltaic module 100 according to one embodiment of the present invention. This diagram is merely an example, which should not unduly limit the scope of the claims. One of ordinary skill in the art would recognize many variations, alternatives, and modifications. As shown in FIG. 3, the method 310 includes a process 300 for providing a substrate; a process 301 for forming an active layer and conductive electrodes; a process 302 for forming sub-module contacts; a process 303 for providing insulators for crossing points; a process 304 for forming bus bars; and a process 305 for completing device fabrication. According to certain embodiments, the method 310 of manufacturing interconnected sub-modules 110 on a substrate 120 can be performed using variations among the processes 300-305 as would be recognized by one of ordinary skill in the art.

At the process 300, the substrate 120 is provided. In one example, the substrate 120 includes glass and/or one or more other transparent materials. In another example, the substrate 120 includes one or more patterned and/or un-patterned films. In yet another example, the photovoltaic module 100 is formed on a single substrate 120.

At the process 301, the active layer 122 and conductive electrodes (e.g., the front electrode 121 and/or the back electrode 123) are formed. For example, the active layer 122 includes an n-type semiconductor region, including a material such as cadmium sulfide, and a p-type semiconductor region, including a material such as cadmium telluride. In another example, the active layer 122 and the conductive electrodes (e.g., the front electrodes 121 and the back electrodes 123) are formed by various processing techniques such as deposition, laser scribing, printing, and/or thermal treatments. In another example, the process 301 includes forming multiple layers of metals oxides, semiconductors, and/or insulators. In yet another example, the process 301 includes the deposition of cadmium sulfide, followed by thermal treatment at 300-600° C.; afterwards, cadmium telluride is deposited and then thermally treated at 300-600° C. In yet another example, the active layer 122 and conductive electrodes form the plurality of photovoltaic cells 101. In yet another example, the photovoltaic cells 101 are formed to create the plurality of sub-modules 110. In yet another example, at the process 301, the plurality of sub-modules 110 are formed.

At the process 302, the sub-module front contacts 111 and the sub-module back contacts 112 are formed. In one example, the sub-module front contacts 111 and the sub-module back contacts 112 are made of one or more materials of low resistivity. In another example, the sub-module front contacts 111 and/or the sub-module back contacts 112 include one or more metal tapes. In yet another example, the sub-module front contacts 111 and/or the sub-module back contacts 112 includes aluminum, copper, and/or tin-plated copper. In yet another example, the sub-module front contacts 111 and/or the sub-module back contacts 112 vary in width from 1 mm to 10 mm. In yet another example, the sub-module front contacts 111 and/or the sub-module back contacts 112 vary in thickness from 30 μm to 300 μm. In yet another example, the sub-module front contacts 111 and/or the sub-module back contacts 112 include one or more conductive adhesive materials for electrical contacts. In yet another example, the sub-module front contacts 111 and/or the sub-module back contacts 112 are ultrasonically welded and/or soldered.

At the process 303, one or more insulators for crossing points are provided. For example, one or more insulators are provided for the locations where the bus bars (e.g., the front bus bars 115 and/or the back bus bars 114) cross over other conductive (e.g., metal) elements in the photovoltaic module 100, such as the sub-module front contacts 111 and/or the sub-module back contact 112. In another example, the one or more insulators can prevent undesired electrical connections between bus bars and other conductive (e.g., metal) elements in the photovoltaic module 100. In yet another example, the insulators include photoresist (e.g., SU-8), adhesive polymer tape, (e.g., polyimide tape), and/or polymer film without adhesive (e.g., polyethylene film without adhesive). In yet another example, the one or more insulators have sufficient thickness to prevent dielectric breakdown when exposed to the maximum voltage differential within the photovoltaic module 100. In yet another example, the one or more insulators vary in thickness from 1 μm to 100 μm.

At the process 304, one or more bus bars (e.g., the front bus bar 115 and/or the back bus bar 114) are formed. In one example, the one or more bus bars are connected to the sub-module front contacts 111 and/or the sub-module back contacts 112 using one or more conductive adhesive materials, one or more ultrasonic welds, one or more physical contacts, and/or one or more solder joints. In another example, the one or more bus bars have a resistance less than 0.1Ω or 0.01Ω. In yet another example, the overall resistance along the length of any given bus bar causes less than a 1% power loss in the photovoltaic module 100 when the photovoltaic module 100 is operating at its maximum power point.

At the process 305, the fabrication of the photovoltaic module 100 is completed. In one example, the process 305 includes encapsulating the interconnected sub-modules 110 for protection from the environment. In another example, the process 305 includes adding edge connectors, corner connectors, and/or wires in order to couple together multiple photovoltaic modules in the field.

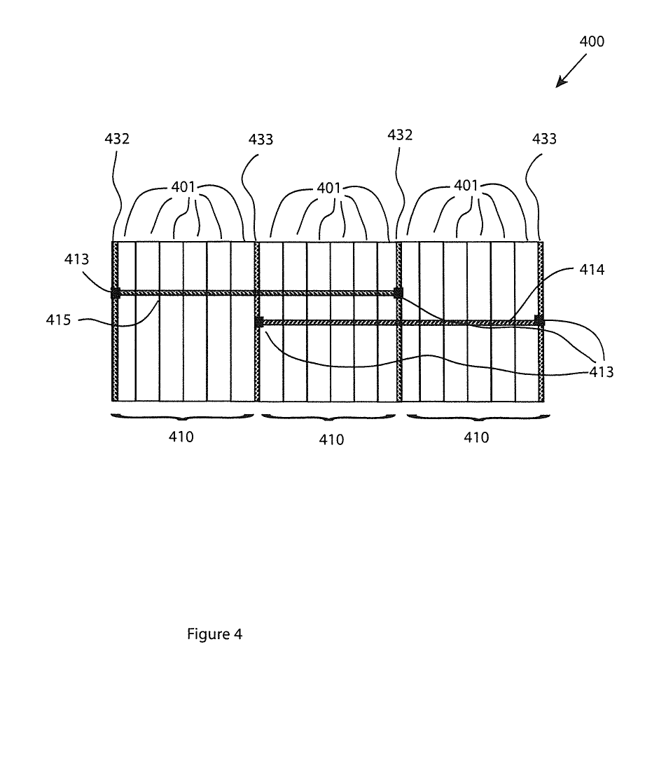

FIG. 4 is a simplified diagram showing a planar view of a photovoltaic module according to another embodiment of the present invention. This diagram is merely an example, which should not unduly limit the scope of the claims. One of ordinary skill in the art would recognize many variations, alternatives, and modifications. In FIG. 4, the photovoltaic module 400 includes a plurality of photovoltaic cells 401. In one example, the photovoltaic cells 401 are interconnected to neighboring photovoltaic cells 401. In another example, the photovoltaic cells 401 are thin film photovoltaic cells.

According to one embodiment, the photovoltaic cells 401 are interconnected to form a plurality of sub-modules 410. In one example, each of the plurality of sub-modules 410 are different in their locations even if they include the same internal structure. In another example, at least some of the sub-modules 410 include a shared sub-module front contact 432 that is shared with a neighboring sub-module 410. In yet another example, each of the shared sub-module front contacts 432 are different in their locations even if they include the same internal structure. In yet another example, at least some of the sub-modules 410 include a shared sub-module back contact 433 that is shared with a neighboring sub-module 410. In yet another example, each of the share sub-module back contacts 433 are different in their locations even if they include the same internal structure. In yet another example, one or more of the shared sub-module front contacts 432 and/or one or more of the shared sub-module back contacts 433 include elements for resistance reduction such as metal foil to reduce electrical resistive losses. In yet another example, one or more of the sub-modules 410 includes a sub-module front contact that is not shared with another sub-module 410. In yet another example, one or more of the sub-modules 410 includes a sub-module back contact that is not shared with another sub-module 410.

According to another embodiment, the sub-module front contacts (e.g., the shared sub-module front contacts 432) are connected (e.g., wired) together and the sub-module back contacts (e.g., the shared sub-module back contacts 433) are connected (e.g., wired) together. For example, the sub-module front contacts are connected to one or more front bus bars 415 using one or more interconnects 413. In another example, each of the one or more front bus bars 415 are different in their locations even if they include the same internal structure. In yet another example, the sub-module back contacts are connected to one or more back bus bars 414 using one or more additional interconnects 413. In yet another example, each of the one or more back bus bars 414 are different in their locations even if they include the same internal structure. In yet another example, the plurality of sub-modules 410 are connected in parallel by the one or more bus bars 414 and 415 through the interconnects 413. In yet another example, one or more of the front bus bars 415 and/or the back bus bars 414 include one or more metal foils. In yet another example, one or more of the front bus bars 415 and/or the back bus bars 414 includes one or more wires. In yet another example, one or more of the front bus bars 415 and/or the back bus bars 414 are insulated to prevent shorting to the backs of the photovoltaic cells 401 and/or to each other.

According to yet another embodiment, the interconnects 413 provide one or more low resistance connections between the sub-module front contacts (e.g., the shared sub-module front contacts 432) and the front bus bars 415, and/or provide one or more low resistance connections between the sub-module back contacts (e.g., the shared sub-module back contacts 433) and the back bus bars 414. In one example, the interconnects 413 provide a physical contact between conductive materials (e.g. metals). In another example, the interconnects 413 use one or more conductive adhesive materials. In yet another example, the interconnects 413 use one or more ultrasonic welds. In yet another example, the interconnects 413 use one or more solder joints (e.g., low temperature solder joints).

According to yet another embodiment, the number of photovoltaic cells 401 per sub-module 410 can be varied depending upon the desired current and voltage characteristic needed for the photovoltaic module 400. In one example, each sub-module 410 includes one or more photovoltaic cells 401. In another example, each sub-module 410 includes as many as half the photovoltaic cells 401 included in the photovoltaic module 400.

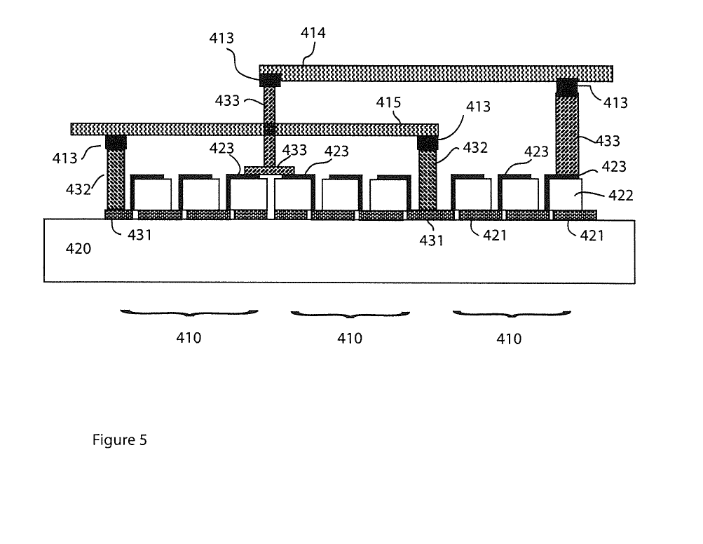

FIG. 5 is a simplified diagram showing a side view of the photovoltaic module 400 according to another embodiment of the present invention. This diagram is merely an example, which should not unduly limit the scope of the claims. One of ordinary skill in the art would recognize many variations, alternatives, and modifications. In FIG. 5, the photovoltaic module 400 includes a plurality of interconnected sub-modules 410. For example, all of the sub-modules 410 are mounted on a substrate 420. In another example, all of the sub-modules 410 are mounted on the same substrate 420. In yet another example, at least two of the sub-modules 410 are oriented so that they share the same shared sub-module front contact 432. In yet another example, at least two of the sub-modules 410 are oriented so that they share the same shared sub-module back contact 433.

According to one embodiment, each of the photovoltaic cells 401 includes an active layer 422 coupled between a front electrode 421 and a back electrode 423. In one example, the active layer 422 includes an n-type semiconductor region, including a material such as cadmium sulfide, and a p-type semiconductor region, including a material such as cadmium telluride. In another example, the n-type semiconductor region is coupled between the p-type semiconductor region and the front electrode 421. In yet another example, the P-type semiconductor region is coupled between the n-type semiconductor region and the back electrode 423. In yet another example, one or more of the front electrodes 421 are of a transparent conductive material such as a metal oxide. In yet another example, as shown in FIG. 4, the front electrode 421 of a photovoltaic cell 401 is coupled to the back electrode 423 of another photovoltaic cell 401 within the same sub-module 410. In yet another example, a shared front electrode 431 of two photovoltaic cells 401 are coupled to a corresponding shared sub-module front contact 432. In yet another example, the back electrodes 423 of two photovoltaic cells 401 are not shared but are coupled to the same corresponding shared sub-module back contact 433. In yet another example, each of the back electrodes 423 are different in their locations even if they include the same internal structure.

As discussed above and further emphasized here, FIGS. 4 and 5 are merely examples, which should not unduly limit the scope of the claims. One of ordinary skill in the art would recognize many variations, alternatives, and modifications. For example, each of the plurality of sub-modules 410 is replaced by at least two modules that are interconnected in series. In another example, the front electrodes 421 of two photovoltaic cells 401 are not shared but are coupled to the same corresponding shared sub-module front contact 432. In yet another example, each of the front electrodes 421 are different in their locations even if they include the same internal structure. In yet another example, a shared back electrode of two photovoltaic cells 401 are coupled to a corresponding shared sub-module back contact 433. In yet another example, one or more of the front bus bars 415 and/or the back bus bars 414 are replaced by conductive materials in other forms. In yet another example, each of the plurality of photovoltaic cells 401 includes one or more photovoltaic materials (e.g., silicon, cadmium telluride, CIGS, and/or organics). In another example, the n-type semiconductor region is coupled between the p-type semiconductor region and the back electrode 423. In yet another example, the p-type semiconductor region is coupled between the n-type semiconductor region and the front electrode 421. In yet another example, the p-type semiconductor region is coupled between the n-type semiconductor region and the shared front electrode 431.

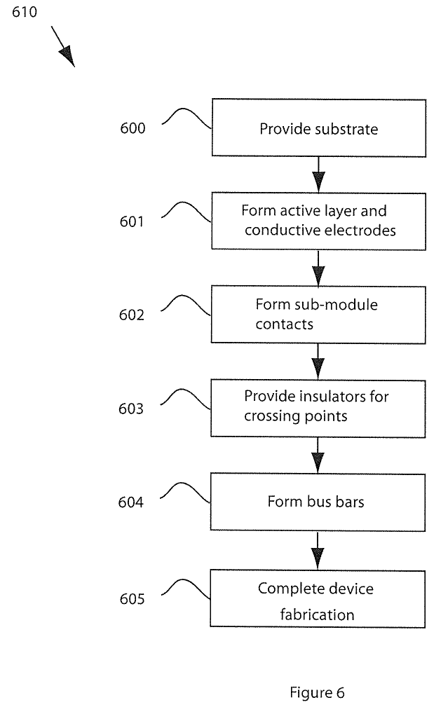

FIG. 6 is a simplified diagram showing a method for making the photovoltaic module 400 according to one embodiment of the present invention. This diagram is merely an example, which should not unduly limit the scope of the claims. One of ordinary skill in the art would recognize many variations, alternatives, and modifications. As shown in FIG. 6, the method 610 includes a process 600 for providing a substrate; a process 601 for forming an active layer and conductive electrodes; a process 602 for forming sub-module contacts; a process 603 for providing insulators for crossing points; a process 604 for forming bus bars; and a process 605 for completing device fabrication. According to certain embodiments, the method 610 of manufacturing interconnected sub-modules 410 on a substrate 420 can be performed using variations among the processes 600-605 as would be recognized by one of ordinary skill in the art.

At the process 600, the substrate 420 is provided. In one example, the substrate 420 includes glass and/or one or more other transparent materials. In another example, the substrate 420 includes one or more patterned and/or un-patterned films. In yet another example, the photovoltaic module 400 is formed on a single substrate 420.

At the process 601, the active layer 422 and conductive electrodes (e.g., the front electrode 421, the shared front electrode 431, and/or the back electrode 423) are formed. For example, the active layer 422 includes an n-type semiconductor region, including a material such as cadmium sulfide, and a p-type semiconductor region, including a material such as cadmium telluride. In another example, the active layer 422 and the conductive electrodes (e.g., the front electrodes 421, the shared front electrodes 431, and/or the back electrodes 423) are formed by various processing techniques such as deposition, laser scribing, printing, and/or thermal treatments. In another example, the process 601 includes forming multiple layers of metals oxides, semiconductors, and/or insulators. In yet another example, the process 601 includes the deposition of cadmium sulfide, followed by thermal treatment at 300-600° C.; afterwards, cadmium telluride is deposited and then thermally treated at 300-600° C. In yet another example, the active layer 422 and conductive electrodes form the plurality of photovoltaic cells 401. In yet another example, the photovoltaic cells 401 are formed to create the plurality of sub-modules 410. In yet another example, at the process 601, the plurality of sub-modules 410 are formed.

At the process 602, the sub-module front contacts (e.g., the shared sub-module front contacts 432) and the sub-module back contacts (e.g., the shared sub-module back contacts 433) are formed. In one example, the sub-module front contacts and the sub-module back contacts are made of one or more materials of low resistivity. In another example, the sub-module front contacts and the sub-module back contacts include one or more metal tapes. In yet another example, the sub-module front contacts and the sub-module back contacts include aluminum, copper, and/or tin-plated copper. In yet another example, the sub-module front contacts and the sub-module back contacts vary in width from 1 mm to 10 mm. In yet another example, the sub-module front contacts and the sub-module back contacts vary in thickness from 30 μm to 300 μm. In yet another example, the sub-module front contacts and the sub-module back contacts include one or more conductive adhesive materials for electrical contacts. In yet another example, the sub-module front contacts and the sub-module back contacts are ultrasonically welded and/or soldered.

At the process 603, one or more insulators for crossing points are provided. For example, one or more insulators are provided for the locations where the bus bars (e.g., the front bus bars 415 and/or the back bus bars 414) cross over other conductive (e.g., metal) elements in the photovoltaic module 100, such as the sub-module front contacts and the sub-module back contacts. In another example, the one or more insulators can prevent undesired electrical connections between bus bars and other conductive (e.g., metal) elements in the photovoltaic module 400. In yet another example, the insulators include photoresist (e.g., SU-8), adhesive polymer tape, (e.g., polyimide tape), and/or polymer film without adhesive (e.g., polyethylene film without adhesive). In yet another example, the one or more insulators have sufficient thickness to prevent dielectric breakdown when exposed to the maximum voltage differential within the photovoltaic module 100. In yet another example, the one or more insulators vary in thickness from 1 μm to 100 μm.

At the process 604, one or more bus bars (e.g., the front bus bar 415 and/or the back bus bar 414) are formed. In one example, the one or more bus bars are connected to the sub-module front contacts and/or the sub-module back contacts using one or more conductive adhesive materials, one or more ultrasonic welds, one or more physical contacts, and/or one or more solder joints. In another example, the one or more bus bars have a resistance less than 0.1Ω or 0.01Ω. In yet another example, the overall resistance along the length of any given bus bar causes less than a 1% power loss in the photovoltaic module 400 when the photovoltaic module 400 is operating at its maximum power point.

At the process 605, the fabrication of the photovoltaic module 400 is completed. In one example, the process 605 includes encapsulating the interconnected sub-modules 410 for protection from the environment. In another example, the process 605 includes adding edge connectors, corner connectors, and/or wires in order to couple together multiple photovoltaic modules in the field.

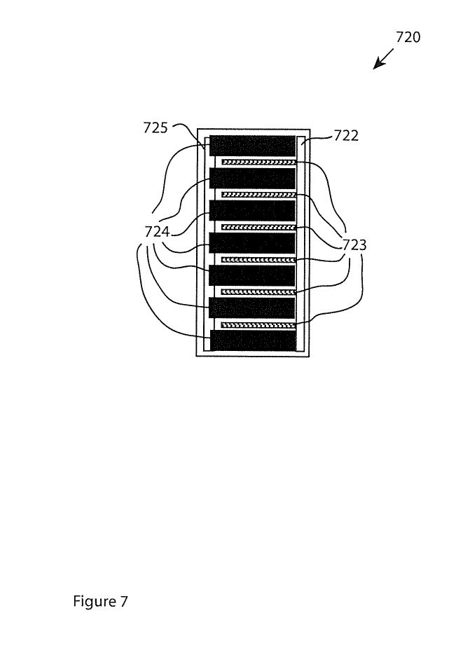

FIG. 7 is a simplified diagram showing a planar view of a photovoltaic sub-module according to one embodiment of the present invention. This diagram is merely an example, which should not unduly limit the scope of the claims. One of ordinary skill in the art would recognize many variations, alternatives, and modifications. In FIG. 7, the photovoltaic sub-module 720 includes a plurality of photovoltaic cells. In one example, the photovoltaic cells are interconnected to neighboring photovoltaic cells. In another example, the photovoltaic cells are thin film photovoltaic cells.

According to one embodiment, the photovoltaic cells are interconnected to form the sub-module 720. In one example, the sub-module 720 includes one or more front electrodes 723. In yet another example, the sub-module 720 includes a plurality of back electrodes 724. In yet another example, the one or more front electrodes 723 are interleaved with the plurality of back electrodes 724.

According to another embodiment, the one or more front electrodes 723 are connected (e.g., wired) together and the plurality of back electrodes 724 are connected (e.g., wired) together. For example, the one or more front electrodes 723 are connected to a front bus bar 722. In another example, the plurality of back electrodes 724 are connected to a back bus bar 725. In yet another example, the front bus bar 722 and/or the back bus bar 725 include one or more metal foils. In yet another example, the front bus bar 722 and/or the back bus bar 725 includes one or more wires. In yet another example, the front bus bar 722 and/or the back bus bar 725 are insulated to prevent shorting to the photovoltaic cells and/or to each other.

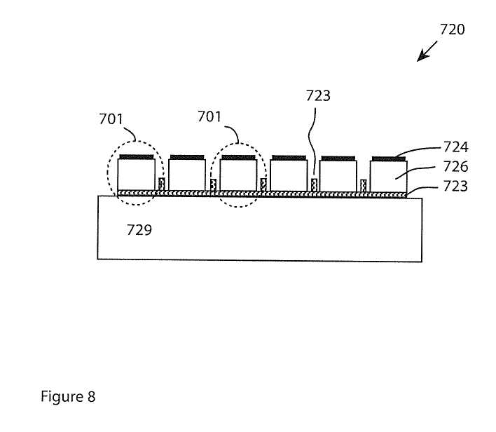

FIG. 8 is a simplified diagram showing a cross-sectional view of the photovoltaic sub-module 720 according to one embodiment of the present invention. This diagram is merely an example, which should not unduly limit the scope of the claims. One of ordinary skill in the art would recognize many variations, alternatives, and modifications. In FIG. 8, the photovoltaic sub-module 720 includes a plurality of interconnected photovoltaic cells 701. For example, all of the photovoltaic cells 701 are mounted on a substrate 729. In another example, all of the photovoltaic cells 701 are mounted on the same substrate 729. In yet another example, all of the photovoltaic cells 701 share a common front electrode 723.

According to one embodiment, each of the photovoltaic cells 701 includes an active layer 726 coupled between the front electrode 723 and a back electrode 724. In one example, the active layer 726 includes an n-type semiconductor region, including a material such as cadmium sulfide, and a p-type semiconductor region, including a material such as cadmium telluride. In another example, the n-type semiconductor region is coupled between the p-type semiconductor region and the front electrode 723. In yet another example, the p-type semiconductor region is coupled between the n-type semiconductor region and the back electrode 724. In yet another example, one or more of the front electrodes 723 are of a transparent conductive material such as a metal oxide.

As discussed above and further emphasized here, FIGS. 7 and 8 are merely examples, which should not unduly limit the scope of the claims. One of ordinary skill in the art would recognize many variations, alternatives, and modifications. For example, the one or more front electrodes 723 need not be shared among the photovoltaic cells 701. In yet another example, the photovoltaic cells 701 share a common back electrode. In yet another example, the front bus bar 722 and/or the back bus bar 725 are replaced by conductive materials in other forms. In yet another example, each of the plurality of photovoltaic cells 701 includes any type of photovoltaic materials (e.g., silicon, cadmium telluride, CIGS, and/or organics). In another example, the n-type semiconductor region is coupled between the p-type semiconductor region and the back electrode 724. In yet another example, the p-type semiconductor region is coupled between the n-type semiconductor region and the front electrode 723. In yet another example, one or more grid line contacts connect the one or front electrodes 723 to the front bus bar 722. In yet another example, one or more grid line contacts connect the back electrodes 724 to the back bus bar 725.

In another embodiment, the photovoltaic sub-module 720 forms a super cell photovoltaic cell 720. For example, the super cell 720 includes one or more front electrodes 723 interleaved with back electrodes 724. In another example, the front electrodes 723 are connected by a front bus bar 722 and the back electrodes 724 are connected by a back bus bar 725. In yet another example, the front bus bar 722 and the back bus bar 725 are located along the edge of the super cell 720. In yet another example, the front bus bar 722 and the back bus bar 725 are, are located behind the super cell 720 to maximize active area. In yet another example, the spacing of the interleaved front electrodes 723 and the back electrodes 724 is relatively short (e.g., 1 cm) while the distance between front bus bar 722 and the back bus bar 725 is longer (e.g., 10 cm).

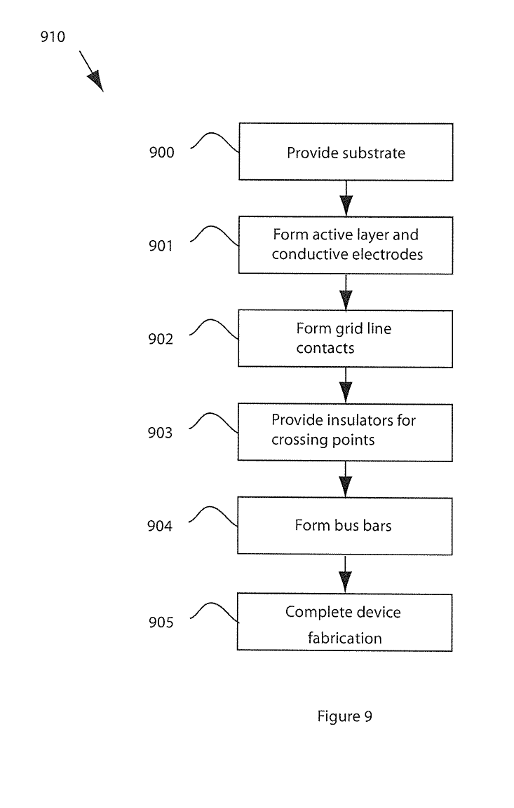

FIG. 9 is a simplified diagram showing a method for making the photovoltaic sub-module 720 according to one embodiment of the present invention. This diagram is merely an example, which should not unduly limit the scope of the claims. One of ordinary skill in the art would recognize many variations, alternatives, and modifications. As shown in FIG. 9, the method 910 includes a process 900 for providing a substrate; a process 901 for forming an active layer and conductive electrodes; a process 902 for forming grid-line contacts; a process 903 for providing insulators for crossing points; a process 904 for forming bus bars; and a process 905 for completing device fabrication. According to certain embodiments, the method 910 of manufacturing photovoltaic sub-modules 720 on a substrate 729 can be performed using variations among the processes 900-905 as would be recognized by one of ordinary skill in the art.

At the process 900, the substrate 729 is provided. In one example, the substrate 729 includes glass and/or one or more other transparent materials. In another example, the substrate 729 includes one or more patterned and/or un-patterned films. In yet another example, the photovoltaic sub-module 720 is formed on a single substrate 729.

At the process 901, the active layer 726 and conductive electrodes (e.g., the front electrode 723 and/or the back electrode 724) are formed. For example, the active layer 726 includes an n-type semiconductor region, including a material such as cadmium sulfide, and a p-type semiconductor region, including a material such as cadmium telluride. In another example, the active layer 726 and the conductive electrodes (e.g., the front electrodes 723 and/or the back electrodes 724) are formed by various processing techniques such as deposition, laser scribing, printing, and/or thermal treatments. In another example, the process 901 includes forming multiple layers of metals oxides, semiconductors, and/or insulators. In yet another example, the process 901 includes the deposition of cadmium sulfide, followed by thermal treatment at 300-600° C.; afterwards, cadmium telluride is deposited and then thermally treated at 300-600° C. In yet another example, the active layer 726 and conductive electrodes form the plurality of photovoltaic cells 701. In yet another example, the photovoltaic cells 701 are formed to create the sub-module 720.

At the process 902, the grid line contacts are formed. In one example, the grid line contacts are made of one or more materials of low resistivity. In another example, the grid line contacts include one or more metal tapes. In yet another example, the grid line contacts include aluminum, copper, and/or tin-plated copper. In yet another example, the grid line contacts vary in width from 1 mm to 10 mm. In yet another example, the grid line contacts vary in thickness from 30 μm to 300 μm. In yet another example, the grid line contacts include one or more conductive adhesive materials for electrical contacts. In yet another example, the grid line contacts are ultrasonically welded and/or soldered.

At the process 903, one or more insulators for crossing points are provided. For example, one or more insulators are provided for the locations where the bus bars (e.g., the front bus bar 722 and/or the back bus bar 725) cross over other conductive (e.g., metal) elements in the photovoltaic sub-module 720, such as the grid line contacts. In another example, the one or more insulators can prevent undesired electrical connections between bus bars and other conductive (e.g., metal) elements in the photovoltaic sub-module 720. In yet another example, the insulators include photoresist, (e.g., SU-8), adhesive polymer tape, (e.g., polyimide tape), and/or polymer film (e.g., polyethylene film) without adhesive. In yet another example, the one or more insulators have sufficient thickness to prevent dielectric breakdown when exposed to the maximum voltage differential within the module. In yet another example, the one or more insulators vary in thickness from 1 μm to 100 μm.

At the process 904, one or more bus bars (e.g., the front bus bar 722 and/or the back bus bar 725) are formed. In one example, the one or more bus bars are connected to the grid line contacts, the front electrodes 723, and/or the back electrodes 724 using one or more conductive adhesive materials, one or more ultrasonic welds, one or more physical contacts, and/or one or more solder joints. In another example, the one or more bus bars have a resistance less than 0.1Ω or 0.01Ω. In yet another example, the overall resistance along the length of any given bus bar causes less than a 1% power loss in the photovoltaic sub-module 720 when the photovoltaic sub-module 720 is operating at its maximum power point.

At the process 905, the fabrication of the photovoltaic sub-module 720 is completed. In one example, the process 905 includes encapsulating the sub-module 720 for protection from the environment. In another example, the process 905 includes adding edge connectors, corner connectors, and/or wires in order to couple together multiple photovoltaic sub-modules.

According to one embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first back electrode is located between the first front electrode and the second front electrode. The second front electrode is located between the first back electrode and the second back electrode. The first sub-module and the second sub-module are different and the first bus bar and the second bus bar are different. For example, the photovoltaic module is implemented according to at least FIG. 1 and/or FIG. 2.

In another example, the first plurality of photovoltaic cells includes at least an additional photovoltaic cell connected in series between the first photovoltaic cell and the second photovoltaic cell. In yet another example, the second plurality of photovoltaic cells includes at least an additional photovoltaic cell connected in series between the third photovoltaic cell and the fourth photovoltaic cell. In yet another example, the photovoltaic module further includes a first front contact and a second front contact different from the first front contact. The first bus bar is electrically connected to the first front electrode through the first front contact and the first bus bar is electrically connected to the second front electrode through the second front contact. In yet another example, the photovoltaic module further includes a first back contact and a second back contact different from the first back contact. The second bus bar is electrically connected to the first back electrode through the first back contact and the second bus bar is electrically connected to the second back electrode through the second back contact. In yet another example, the first back contact is located between the first front contact and the second front contact and the second front contact is located between the first back contact and the second back contact.

In yet another example, the photovoltaic module further includes a first interconnect electrically connecting the first front contact and the first bus bar, a second interconnect electrically connecting the second front contact and the first bus bar, a third interconnect electrically connecting the first back contact and the second bus bar, and a fourth interconnect electrically connecting the second back contact and the second bus bar. In yet another example, the first photovoltaic cell includes a first n-type semiconductor layer directly or indirectly connected to the first front electrode, the second photovoltaic cell includes a first p-type semiconductor layer directly or indirectly connected to the first back electrode, the third photovoltaic cell includes a second n-type semiconductor layer directly or indirectly connected to the second front electrode, and the fourth photovoltaic cell includes a second p-type semiconductor layer directly or indirectly connected to the second back electrode. In yet another example, each of the first p-type semiconductor layer and the second p-type semiconductor layer includes cadmium telluride and each of the first n-type semiconductor layer and the second n-type semiconductor layer includes cadmium sulfide. In yet another example, the first sub-module and the second sub-module are located on a same substrate. In yet another example, the substrate includes glass. In yet another example, each of the first bus bar and the second bus bar includes one or more metal foils. In yet another example, each of the first bus bar and the second bus bar includes one or more wires.

According to another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell including a second back electrode. Additionally, the method for making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first back electrode between the first front electrode and the second front electrode and placing the second front electrode between the first back electrode and the second back electrode. The process for forming a first sub-module on the substrate and the process for forming a second sub-module on the substrate are different. The process for forming a first bus bar and the process for forming a second bus bar are different. For example, the method is implemented according to at least FIG. 3.

According to yet another embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first back electrode is located between the first front electrode and the second front electrode. The second back electrode is located between the first front electrode and the second front electrode. The first sub-module and the second sub-module are different and the first bus bar and the second bus bar are different. For example, the photovoltaic module is implemented according to at least FIG. 4 and/or FIG. 5.

In another example, the first back electrode and the second back electrode are different, the first back electrode is located between the first front electrode and the second back electrode, and the second back electrode is located between the first back electrode and the second front electrode. In yet another example, the first back electrode is the second back electrode. In yet another example, the first plurality of photovoltaic cells includes at least an additional photovoltaic cell connected in series between the first photovoltaic cell and the second photovoltaic cell. In yet another example, the second plurality of photovoltaic cells includes at least an additional photovoltaic cell connected in series between the third photovoltaic cell and the fourth photovoltaic cell. In yet another example, the photovoltaic module further includes a first front contact and a second front contact. The first bus bar is electrically connected to the first front electrode through the first front contact and the first bus bar is electrically connected to the second front electrode through the second front contact. In yet another example, the photovoltaic module further includes a first back contact and a second back contact. The second bus bar is electrically connected to the first back electrode through the first back contact and the second bus bar is electrically connected to the second back electrode through the second back contact. In yet another example, the first back contact is different from the second back contact, the first back contact is located between the first front contact and the second back contact, and the second back contact is located between the first back contact and the second front contact. In yet another example, the first back contact is the second back contact and the first back contact is located between the first front contact and the second front contact.

In yet another example, the first photovoltaic cell includes a first n-type semiconductor layer directly or indirectly connected to the first front electrode, the second photovoltaic cell includes a first p-type semiconductor layer directly or indirectly connected to the first back electrode, the third photovoltaic cell includes a second n-type semiconductor layer directly or indirectly connected to the second front electrode, and the fourth photovoltaic cell includes a second p-type semiconductor layer directly or indirectly connected to the second back electrode. In yet another example, each of the first p-type semiconductor layer and the second p-type semiconductor layer includes cadmium telluride, and each of the first n-type semiconductor layer and the second n-type semiconductor layer includes cadmium sulfide. In yet another example, the first sub-module and the second sub-module are located on a same substrate. In yet another example, the substrate includes glass. In yet another example, each of the first bus bar and the second bus bar includes one or more metal foils. In yet another example, each of the first bus bar and the second bus bar includes one or more wires.

According to yet another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell includes a second back electrode. Additionally, the method for making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first back electrode between the first front electrode and the second front electrode and placing the second back electrode between the first front electrode and the second front electrode. The process for forming a first sub-module on the substrate and the process for forming a second sub-module on the substrate are different. The process for forming a first bus bar and the process for forming a second bus bar are different. For example, the method is implemented according to at least FIG. 6.

According to yet another embodiment, a photovoltaic module includes a first sub-module and a second sub-module. The first sub-module includes a first plurality of photovoltaic cells. The first plurality of photovoltaic cells is connected in series starting with a first photovoltaic cell and ending with a second photovoltaic cell. The first photovoltaic cell includes a first front electrode. The second photovoltaic cell including a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode. The fourth photovoltaic cell includes a second back electrode. Additionally, the photovoltaic module includes a first bus bar and a second bus bar. The first bus bar is electrically connected to at least the first front electrode and the second front electrode. The second bus bar is electrically connected to at least the first back electrode and the second back electrode. The first front electrode is located between the first back electrode and the second back electrode. The second front electrode is located between the first back electrode and the second back electrode. The first sub-module and the second sub-module are different and the first bus bar and the second bus bar are different. For example, the photovoltaic module is implemented according to at least FIG. 4 and/or FIG. 5.

In another example, the first front electrode and the second front electrode are different, the first front electrode is located between the first back electrode and the second front electrode, and the second front electrode is located between the first front electrode and the second back electrode. In yet another example, the first front electrode is the second front electrode. In yet another example, the first plurality of photovoltaic cells includes at least an additional photovoltaic cell connected in series between the first photovoltaic cell and the second photovoltaic cell. In yet another example, the second plurality of photovoltaic cells includes at least an additional photovoltaic cell connected in series between the third photovoltaic cell and the fourth photovoltaic cell. In yet another example, the photovoltaic module further includes a first front contact and a second front contact. The first bus bar is electrically connected to the first front electrode through the first front contact. The first bus bar is electrically connected to the second front electrode through the second front contact. In yet another example, the photovoltaic module further includes a first back contact and a second back contact. The second bus bar is electrically connected to the first back electrode through the first back contact. The second bus bar is electrically connected to the second back electrode through the second back contact. In yet another example, the first front contact is different from the second front contact, the first front contact is located between the first back contact and the second front contact, and the second front contact is located between the first front contact and the second back contact. In yet another example, the first front contact is the second front contact and the first front contact is located between the first back contact and the second back contact.

In yet another example, the first photovoltaic cell includes a first n-type semiconductor layer directly or indirectly connected to the first front electrode, the second photovoltaic cell includes a first p-type semiconductor layer directly or indirectly connected to the first back electrode, the third photovoltaic cell includes a second n-type semiconductor layer directly or indirectly connected to the second front electrode, and the fourth photovoltaic cell includes a second p-type semiconductor layer directly or indirectly connected to the second back electrode. In yet another example, each of the first p-type semiconductor layer and the second p-type semiconductor layer includes cadmium telluride and each of the first n-type semiconductor layer and the second n-type semiconductor layer includes cadmium sulfide. In yet another example, the first sub-module and the second sub-module are located on a same substrate. In yet another example, the substrate includes glass. In yet another example, each of the first bus bar and the second bus bar includes one or more metal foils. In yet another example, each of the first bus bar and the second bus bar includes one or more wires.

According to yet another embodiment, a method for making a photovoltaic module includes providing a substrate, forming a first sub-module on the substrate, and forming a second sub-module on the substrate. The first sub-module includes a first plurality of photovoltaic cells. The first plurality of photovoltaic cells is connected in series starting with a first photovoltaic cell and ending with a second photovoltaic cell. The first photovoltaic cell includes a first front electrode and the second photovoltaic cell includes a first back electrode. The second sub-module includes a second plurality of photovoltaic cells. The second plurality of photovoltaic cells is connected in series starting with a third photovoltaic cell and ending with a fourth photovoltaic cell. The third photovoltaic cell includes a second front electrode and the fourth photovoltaic cell includes a second back electrode. Additionally, the method of making a photovoltaic module includes electrically connecting a first bus bar to at least the first front electrode and the second front electrode and electrically connecting a second bus bar to at least the first back electrode and the second back electrode. The process for forming a first sub-module on the substrate and the process for forming a second sub-module on the substrate include placing the first front electrode between the first back electrode and the second back electrode and placing the second front electrode between the first back electrode and the second back electrode. The process for forming a first sub-module on the substrate and the process for forming a second sub-module on the substrate are different. The process for forming a first bus bar and the process for forming a second bus bar are different. For example, the method is implemented according to at least FIG. 6.

According to yet another embodiment, a photovoltaic sub-module includes a first photovoltaic cell and a second photovoltaic cell. The first photovoltaic cell includes a first p-type semiconductor layer, a first n-type semiconductor layer, and a first back electrode. The second photovoltaic cell includes a second p-type semiconductor layer, a second n-type semiconductor layer, and a second back electrode. Additionally, the photovoltaic module includes a front electrode, a first bus bar, and a second bus bar. The front electrode is electrically connected to the first photovoltaic cell and the second photovoltaic cell. The first bus bar is electrically connected to the front electrode. The second bus bar is electrically connected to the first back electrode and the second back electrode. The first p-type semiconductor layer and the second p-type semiconductor layer are not directly connected. The first n-type semiconductor layer and the second n-type semiconductor layer are not directly connected. The first bus bar and the second bus bar are different. For example, the photovoltaic module is implemented according to at least FIG. 7 and/or FIG. 8.

According to yet another embodiment, a method for making a photovoltaic sub-module includes providing a substrate, forming a first photovoltaic cell on the substrate, and forming a second photovoltaic cell on the substrate. The first photovoltaic cell includes a first p-type semiconductor layer, a first n-type semiconductor layer, and a first back electrode. The second photovoltaic cell includes a second p-type semiconductor layer, a second n-type semiconductor layer, and a second back electrode. Additionally, the method for making a photovoltaic sub-module includes forming a front electrode, electrically connecting a first bus bar to the front electrode, and electrically connecting a second bus bar to the first back electrode and the second back electrode. The front electrode is electrically connected to the first photovoltaic cell and the second photovoltaic cell. The first p-type semiconductor layer and the second p-type semiconductor layer are not directly connected. The first n-type semiconductor layer and the second n-type semiconductor layer are not directly connected. The process for forming a first bus bar and the process for forming a second bus bar are different. For example, the method is implemented according to at least FIG. 9.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A photovoltaic module, the module comprising:
a first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
a second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
a first bus bar electrically connected to at least the first front electrode and the second front electrode; and
a second bus bar electrically connected to at least the first back electrode and the second back electrode;
wherein:
the first back electrode is located between the first front electrode and the second front electrode; and
the second front electrode is located between the first back electrode and the second back electrode;
wherein:
the first sub-module and the second sub-module are different; and
the first bus bar and the second bus bar are different.

2. The photovoltaic module of claim 1 wherein the first plurality of photovoltaic cells includes at least an additional photovoltaic cell connected in series between the first photovoltaic cell and the second photovoltaic cell.

3. The photovoltaic module of claim 1 wherein the second plurality of photovoltaic cells includes at least an additional photovoltaic cell connected in series between the third photovoltaic cell and the fourth photovoltaic cell.

4. The photovoltaic module of claim 1, and further comprising:
a first front contact; and
a second front contact different from the first front contact;
wherein:
the first bus bar is electrically connected to the first front electrode through the first front contact; and
the first bus bar is electrically connected to the second front electrode through the second front contact.

5. The photovoltaic module of claim 4, and further comprising:
a first back contact; and
a second back contact different from the first back contact;
wherein:
the second bus bar is electrically connected to the first back electrode through the first back contact; and
the second bus bar is electrically connected to the second back electrode through the second back contact.

6. The photovoltaic module of claim 5 wherein:
the first back contact is located between the first front contact and the second front contact; and
the second front contact is located between the first back contact and the second back contact.

7. The photovoltaic module of claim 5, and further comprising:
a first interconnect electrically connecting the first front contact and the first bus bar;
a second interconnect electrically connecting the second front contact and the first bus bar;
a third interconnect electrically connecting the first back contact and the second bus bar; and
a fourth interconnect electrically connecting the second back contact and the second bus bar.

8. The photovoltaic module of claim 1 wherein:
the first photovoltaic cell includes a first n-type semiconductor layer directly or indirectly connected to the first front electrode;
the second photovoltaic cell includes a first p-type semiconductor layer directly or indirectly connected to the first back electrode;
the third photovoltaic cell includes a second n-type semiconductor layer directly or indirectly connected to the second front electrode; and
the fourth photovoltaic cell includes a second p-type semiconductor layer directly or indirectly connected to the second back electrode.

9. The photovoltaic module of claim 8 wherein:
each of the first p-type semiconductor layer and the second p-type semiconductor layer includes cadmium telluride; and
each of the first n-type semiconductor layer and the second n-type semiconductor layer includes cadmium sulfide.

10. The photovoltaic module of claim 1 wherein the first sub-module and the second sub-module are located on a same substrate.

11. The photovoltaic module of claim 10 wherein the substrate includes glass.

12. The photovoltaic module of claim 1 wherein each of the first bus bar and the second bus bar includes one or more metal foils.

13. The photovoltaic module of claim 1 wherein each of the first bus bar and the second bus bar includes one or more wires.

14. A method for making a photovoltaic module, the method comprising:
providing a substrate;
forming a first sub-module on the substrate, the first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
forming a second sub-module on the substrate, the second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
electrically connecting a first bus bar to at least the first front electrode and the second front electrode; and
electrically connecting a second bus bar to at least the first back electrode and the second back electrode;
wherein the process for forming a first sub-module on the substrate and the process for forming a second sub-module on the substrate include:
placing the first back electrode between the first front electrode and the second front electrode; and
placing the second front electrode between the first back electrode and the second back electrode;
wherein:
the process for forming a first sub-module on the substrate and the process for forming a second sub-module on the substrate are different; and
the process for forming a first bus bar and the process for forming a second bus bar are different.

15. A photovoltaic module, the module comprising:
a first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
a second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
a first bus bar electrically connected to at least the first front electrode and the second front electrode; and
a second bus bar electrically connected to at least the first back electrode and the second back electrode;
wherein:
the first back electrode is located between the first front electrode and the second front electrode; and
the second back electrode is located between the first front electrode and the second front electrode;
wherein:
the first sub-module and the second sub-module are different; and
the first bus bar and the second bus bar are different.

16. The photovoltaic module of claim 15 wherein:
the first back electrode and the second back electrode are different;
the first back electrode is located between the first front electrode and the second back electrode; and
the second back electrode is located between the first back electrode and the second front electrode.

17. The photovoltaic module of claim 15 wherein the first back electrode is the second back electrode.

18. The photovoltaic module of claim 15 wherein the first plurality of photovoltaic cells includes at least an additional photovoltaic cell connected in series between the first photovoltaic cell and the second photovoltaic cell.

19. The photovoltaic module of claim 15 wherein the second plurality of photovoltaic cells includes at least an additional photovoltaic cell connected in series between the third photovoltaic cell and the fourth photovoltaic cell.

20. The photovoltaic module of claim 15, and further comprising:
a first front contact; and
a second front contact;
wherein:
the first bus bar is electrically connected to the first front electrode through the first front contact; and
the first bus bar is electrically connected to the second front electrode through the second front contact.

21. The photovoltaic module of claim 20, and further comprising:
a first back contact; and
a second back contact;
wherein:
the second bus bar is electrically connected to the first back electrode through the first back contact; and
the second bus bar is electrically connected to the second back electrode through the second back contact.

22. The photovoltaic module of claim 21 wherein:
the first back contact is different from the second back contact;
the first back contact is located between the first front contact and the second back contact; and
the second back contact is located between the first back contact and the second front contact.

23. The photovoltaic module of claim 21 wherein:
the first back contact is the second back contact; and
the first back contact is located between the first front contact and the second front contact.

24. The photovoltaic module of claim 15 wherein:
the first photovoltaic cell includes a first n-type semiconductor layer directly or indirectly connected to the first front electrode;
the second photovoltaic cell includes a first p-type semiconductor layer directly or indirectly connected to the first back electrode;
the third photovoltaic cell includes a second n-type semiconductor layer directly or indirectly connected to the second front electrode; and
the fourth photovoltaic cell includes a second p-type semiconductor layer directly or indirectly connected to the second back electrode.

25. The photovoltaic module of claim 24 wherein:
each of the first p-type semiconductor layer and the second p-type semiconductor layer includes cadmium telluride; and
each of the first n-type semiconductor layer and the second n-type semiconductor layer includes cadmium sulfide.

26. The photovoltaic module of claim 15 wherein the first sub-module and the second sub-module are located on a same substrate.

27. The photovoltaic module of claim 26 wherein the substrate includes glass.

28. The photovoltaic module of claim 15 wherein each of the first bus bar and the second bus bar includes one or more metal foils.

29. The photovoltaic module of claim 15 wherein each of the first bus bar and the second bus bar includes one or more wires.

30. A method for making a photovoltaic module, the method comprising:
providing a substrate;
forming a first sub-module on the substrate, the first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
forming a second sub-module on the substrate, the second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
electrically connecting a first bus bar to at least the first front electrode and the second front electrode; and
electrically connecting a second bus bar to at least the first back electrode and the second back electrode;
wherein the process for forming a first sub-module on the substrate and the process for forming a second sub-module on the substrate include:
placing the first back electrode between the first front electrode and the second front electrode; and
placing the second back electrode between the first front electrode and the second front electrode;
wherein:
the process for forming a first sub-module on the substrate and the process for forming a second sub-module on the substrate are different; and
the process for forming a first bus bar and the process for forming a second bus bar are different.

31. A photovoltaic module, the module comprising:
a first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
a second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
a first bus bar electrically connected to at least the first front electrode and the second front electrode; and
a second bus bar electrically connected to at least the first back electrode and the second back electrode;
wherein:
the first front electrode is located between the first back electrode and the second back electrode; and
the second front electrode is located between the first back electrode and the second back electrode;
wherein:
the first sub-module and the second sub-module are different; and
the first bus bar and the second bus bar are different.

32. The photovoltaic module of claim 31 wherein:
the first front electrode and the second front electrode are different;
the first front electrode is located between the first back electrode and the second front electrode; and
the second front electrode is located between the first front electrode and the second back electrode.

33. The photovoltaic module of claim 31 wherein the first front electrode is the second front electrode.

34. The photovoltaic module of claim 31 wherein the first plurality of photovoltaic cells includes at least an additional photovoltaic cell connected in series between the first photovoltaic cell and the second photovoltaic cell.

35. The photovoltaic module of claim 31 wherein the second plurality of photovoltaic cells includes at least an additional photovoltaic cell connected in series between the third photovoltaic cell and the fourth photovoltaic cell.

36. The photovoltaic module of claim 31, and further comprising:
a first front contact; and
a second front contact;
wherein:
the first bus bar is electrically connected to the first front electrode through the first front contact; and
the first bus bar is electrically connected to the second front electrode through the second front contact.

37. The photovoltaic module of claim 36, and further comprising:
a first back contact; and
a second back contact;
wherein:
the second bus bar is electrically connected to the first back electrode through the first back contact; and
the second bus bar is electrically connected to the second back electrode through the second back contact.

38. The photovoltaic module of claim 37 wherein:
the first front contact is different from the second front contact;
the first front contact is located between the first back contact and the second front contact; and
the second front contact is located between the first front contact and the second back contact.

39. The photovoltaic module of claim 37 wherein:
the first front contact is the second front contact; and
the first front contact is located between the first back contact and the second back contact.

40. The photovoltaic module of claim 31 wherein:
the first photovoltaic cell includes a first n-type semiconductor layer directly or indirectly connected to the first front electrode;
the second photovoltaic cell includes a first p-type semiconductor layer directly or indirectly connected to the first back electrode;
the third photovoltaic cell includes a second n-type semiconductor layer directly or indirectly connected to the second front electrode; and
the fourth photovoltaic cell includes a second p-type semiconductor layer directly or indirectly connected to the second back electrode.

41. The photovoltaic module of claim 40 wherein:
each of the first p-type semiconductor layer and the second p-type semiconductor layer includes cadmium telluride; and
each of the first n-type semiconductor layer and the second n-type semiconductor layer includes cadmium sulfide.

42. The photovoltaic module of claim 31 wherein the first sub-module and the second sub-module are located on a same substrate.

43. The photovoltaic module of claim 42 wherein the substrate includes glass.

44. The photovoltaic module of claim 31 wherein each of the first bus bar and the second bus bar includes one or more metal foils.

45. The photovoltaic module of claim 31 wherein each of the first bus bar and the second bus bar includes one or more wires.

46. A method for making a photovoltaic module, the method comprising:
providing a substrate;
forming a first sub-module on the substrate, the first sub-module including a first plurality of photovoltaic cells, the first plurality of photovoltaic cells connected in series starting with a first photovoltaic cell and ending with a second photovoltaic cell, the first photovoltaic cell including a first front electrode, the second photovoltaic cell including a first back electrode;
forming a second sub-module on the substrate, the second sub-module including a second plurality of photovoltaic cells, the second plurality of photovoltaic cells connected in series starting with a third photovoltaic cell and ending with a fourth photovoltaic cell, the third photovoltaic cell including a second front electrode, the fourth photovoltaic cell including a second back electrode;
electrically connecting a first bus bar to at least the first front electrode and the second front electrode; and
electrically connecting a second bus bar to at least the first back electrode and the second back electrode;
wherein the process for forming a first sub-module on the substrate and the process for forming a second sub-module on the substrate include:
placing the first front electrode between the first back electrode and the second back electrode; and
placing the second front electrode between the first back electrode and the second back electrode;
wherein:
the process for forming a first sub-module on the substrate and the process for forming a second sub-module on the substrate are different; and
the process for forming a first bus bar and the process for forming a second bus bar are different.

47. A photovoltaic sub-module, the sub-module comprising:
a first photovoltaic cell including a first p-type semiconductor layer, a first n-type semiconductor layer, and a first back electrode;
a second photovoltaic cell including a second p-type semiconductor layer, a second n-type semiconductor layer, and a second back electrode;
a front electrode electrically connected to the first photovoltaic cell and the second photovoltaic cell;
a first bus bar electrically connected to the front electrode; and
a second bus bar electrically connected to the first back electrode and the second back electrode;
wherein:
the first p-type semiconductor layer and the second p-type semiconductor layer are not directly connected;
the first n-type semiconductor layer and the second n-type semiconductor layer are not directly connected; and
the first bus bar and the second bus bar are different.

48. A method for making a photovoltaic sub-module, the method comprising:
providing a substrate;
forming a first photovoltaic cell on the substrate, the first photovoltaic cell including a first p-type semiconductor layer, a first n-type semiconductor layer, and a first back electrode;
forming a second photovoltaic cell on the substrate, the second photovoltaic cell including a second p-type semiconductor layer, a second n-type semiconductor layer, and a second back electrode;
forming a front electrode electrically connected to the first photovoltaic cell and the second photovoltaic cell;
electrically connecting a first bus bar to the front electrode; and
electrically connecting a second bus bar to the first back electrode and the second back electrode;
wherein:
the first p-type semiconductor layer and the second p-type semiconductor layer are not directly connected;
the first n-type semiconductor layer and the second n-type semiconductor layer are not directly connected; and
the process for forming a first bus bar and the process for forming a second bus bar are different.
